(19) United States
(12) Patent Application Publication
(10) Pub. No.: US 2023/0189462 A1
(43) Pub. Date: Jun. 15, 2023

(54) ELECTRONIC DEVICE

(71) Applicant: VIVO MOBILE COMMUNICATION CO., LTD., Dongguan (CN)

(72) Inventors: Sujun GUI, Dongguan (CN); Xiaofeng XU, Dongguan (CN)

(73) Assignee: VIVO MOBILE COMMUNICATION CO., LTD., Dongguan (CN)

(21) Appl. No.: 18/109,834

(22) Filed: Feb. 14, 2023

Related U.S. Application Data
(63) Continuation of application No. PCT/CN2021/113424, filed on Aug. 19, 2021.

(30) Foreign Application Priority Data
Aug. 21, 2020 (CN) 202010847187.4

(51) Int. Cl. H05K 5/02

(52) U.S. Cl. CPC H05K 5/0226

(57) ABSTRACT

This application discloses an electronic device, including a first folding portion, a second folding portion, a connecting portion, a flexible screen, a rotating shaft assembly, and a connecting rod assembly. The first folding portion is rotatably connected to the second folding portion through the connecting portion. The first folding portion, the second folding portion, and the connecting portion form a support structure. The rotating shaft assembly includes a rotating shaft. While the electronic device is being unfolded or folded, the first folding portion or the second folding portion rotate relative to the rotating shaft. The connecting rod assembly includes a first connecting rod and a second connecting rod. While the electronic device is being unfolded, the first connecting rod and the second connecting rod respectively drive the first folding portion and the second folding portion to be away from each other, and the connecting portion is increased.

### CROSS-REFERENCE TO RELATED APPLICATIONS

This application is a continuation of International Application No. PCT/CN2021/113424, filed on Aug. 19, 2021, which claims priority to Chinese Patent Application No. 202010847187.4, filed on Aug. 21, 2020. The entire contents of each of the above-referenced applications are expressly incorporated herein by reference.

### TECHNICAL FIELD

This application pertains to the field of communication devices, and specifically relates to an electronic device.

### BACKGROUND

As electronic devices develop rapidly and people use the electronic devices more frequently, users have more diversified requirements for the electronic devices, especially for large-screen electronic devices. A large screen means an increase of a device size, and accordingly, may cause inconvenience for a user to carry a large-screen electronic device.

To improve user experience, a technological breakthrough and technological development of the flexible screen are implemented. Therefore, combination of a foldable rotating shaft with a flexible screen in the electronic device becomes a development direction, and the flexible screen is not only easily broken, but also thinner and lighter.

However, while implementing this application, the inventor found that a defect exists in the related art. For the present electronic device, a flexible screen is on an outside of the electronic device, and folding is implemented in a small screen. When the folding is implemented in a large screen, the electronic device is required to rotate outward along a rotating shaft. The flexible screen is on an outer side of the rotating shaft, and a middle position of the flexible screen will be wrinkled while the electronic device is being unfolded.

### SUMMARY

Embodiments of this application are intended to provide an electronic device.

This application is implemented as follows.

According to a first aspect, an embodiment of this application provides an electronic device, including a first folding portion, a second folding portion, a connecting portion, a flexible screen, a rotating shaft assembly, and a connecting rod assembly, where the first folding portion is rotatably connected to the second folding portion through the connecting portion, the first folding portion, the second folding portion, and the connecting portion form a support structure, and the flexible screen and the rotating shaft assembly are respectively disposed on a first surface and a second surface of the support structure.

The rotating shaft assembly includes a rotating shaft, the rotating shaft is located at a position that is on the second surface and that is opposite to the connecting portion, while the electronic device is being unfolded or folded, the first folding portion and/or the second folding portion rotate relative to the rotating shaft, in a case that the electronic device is in a folding state, the flexible screen is located on an outer side of the electronic device, and a first portion that is of the flexible screen and that is on the first folding portion is disposed opposite to a second portion that is of the flexible screen and that is on the second folding portion.

The connecting rod assembly includes a first connecting rod and a second connecting rod, where a first end of the first connecting rod is rotatably connected to the rotating shaft assembly, and a second end of the first connecting rod is connected to the first folding portion, a first end of the second connecting rod is rotatably connected to the rotating shaft assembly, and a second end of the second connecting rod is connected to the second folding portion.

While the electronic device is being unfolded, the first connecting rod and the second connecting rod drive the first folding portion and the second folding portion to be away from each other, and the connecting portion is increased.

By improvement of a structure of an electronic device in the related art, the electronic device disclosed in this embodiment of this application is provided with the first folding portion, the second folding portion, the connecting portion, the flexible screen, the rotating shaft assembly, and the connecting rod assembly. The first folding portion is rotatably connected to the second folding portion through the connecting portion. The flexible screen and the rotating shaft assembly are respectively disposed on the first surface and second surface of the support structure formed by the first folding portion, the second folding portion, and the connecting portion. The connecting rod assembly is connected to the rotating shaft assembly, the first folding portion, and the second folding portion, that is, the connecting rod assembly acts as a relatively good support when the first folding portion and the second folding portion rotate relative to each other. While the first folding portion and the second folding portion rotate relative to each other to be unfolded, the first connecting rod and the second connecting rod drive the first folding portion and the second folding portion to be away from each other. Due to unfolding support of the first connecting rod and the second connecting rod, a distance between adjacent edges of the first folding portion and the second folding portion is not reduced due to rotation, and then the flexible screen can be stretched well, an area where the flexible screen is opposite to the connecting portion is not wrinkled, and user experience can be improved finally.

### BRIEF DESCRIPTION OF DRAWINGS

To describe the technical solutions in the embodiments of this application or in the background more clearly, the following briefly describes the accompanying drawings for describing the embodiments or the background. Apparently, a person of ordinary skill in the art may still derive other drawings from these accompanying drawings without creative efforts.

FIG. 1 is a schematic structural exploded diagram of an electronic device according to an embodiment of this application;

FIG. 2 is a schematic structural diagram of the electronic device disclosed according to an embodiment of this application;

FIG. 3 is a partially schematic structural diagram of the electronic device disclosed according to an embodiment of this application;

FIG. 4 is a schematic structural diagram of a rotating shaft assembly of the electronic device disclosed according to embodiment of this application;

FIG. 5 is a locally enlarged view of FIG. 4;

FIG. 6 is a schematic structural diagram of a part of the electronic device disclosed according to an embodiment of this application; and

FIG. 7 is a schematic diagram of a folding process of the electronic device disclosed according to an embodiment of this application.

### DETAILED DESCRIPTION

Embodiments of this application provide an electronic device.

The following describes the technical solutions in the embodiments of this application with reference to the accompanying drawings in the embodiments of this application. Apparently, the described embodiments are some but not all of the embodiments of this application. All other embodiments obtained by a person of ordinary skill in the art based on the embodiments of this application without creative efforts shall fall within the protection scope of this application.

The terms “first”, “second”, and the like in the specification and claims of this application are used to distinguish between similar objects instead of describing a specific order or sequence. It should be understood that data used in this way may be interchangeable in an appropriate case, so that the embodiments of this application can be implemented in a sequence other than those shown or described herein, and objects distinguished by “first” and “second” are generally of a same type, and a quantity of objects is not limited. For example, there may be one or more first targets. In addition, in the specification and the claims, “and/or” represents at least one of connected objects, and a character “/” generally represents an “or” relationship between associated objects.

With reference to the accompanying drawings, an electronic device provided in the embodiments of this application will be described in detail by using examples and application scenarios thereof.

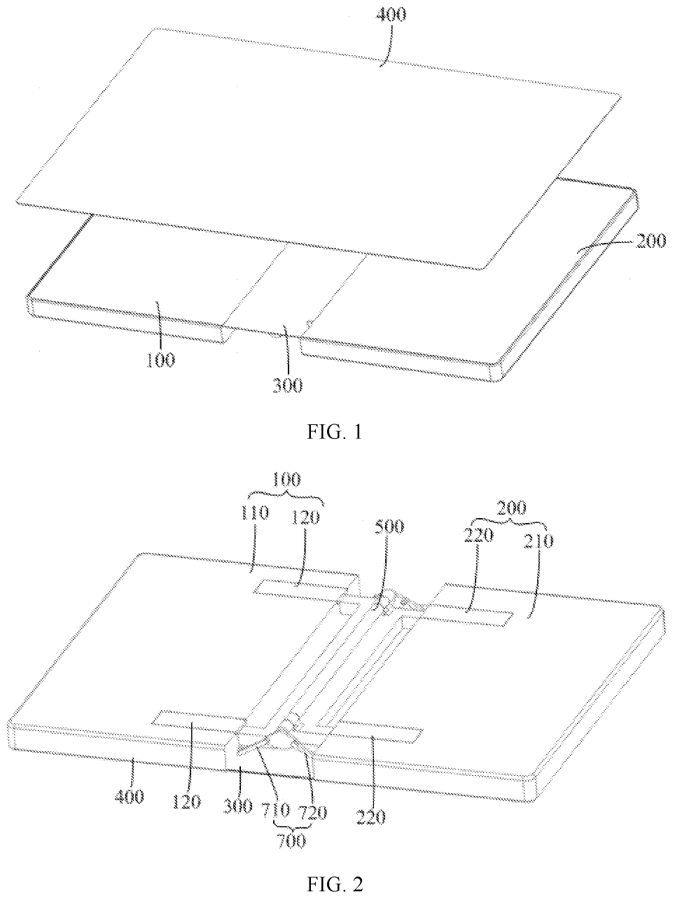

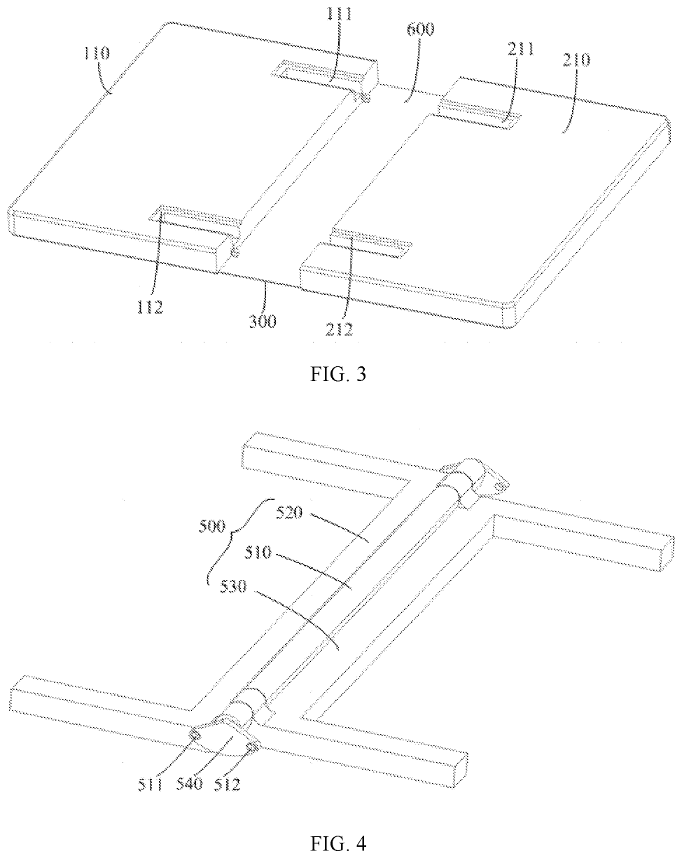

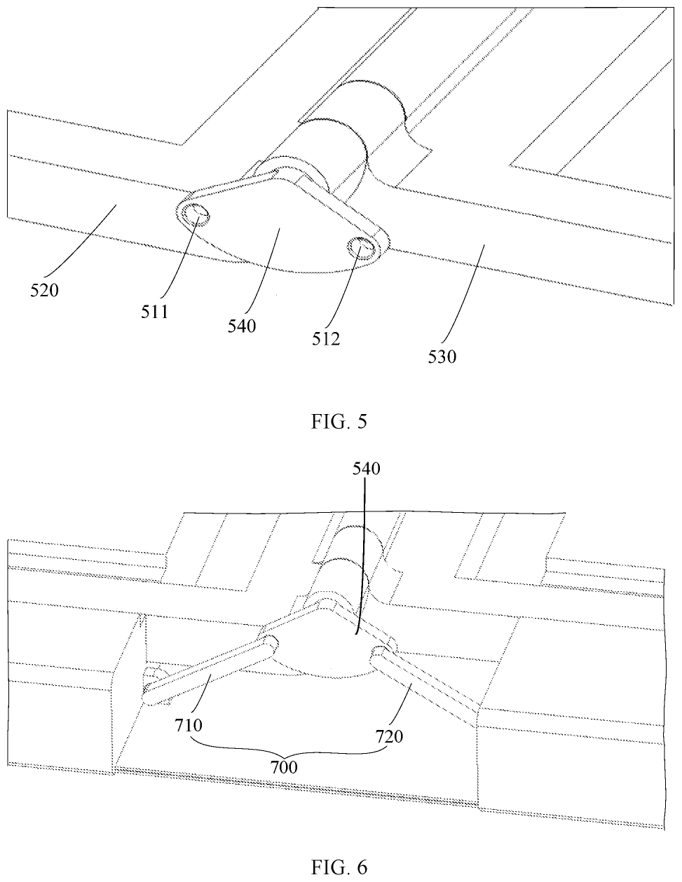

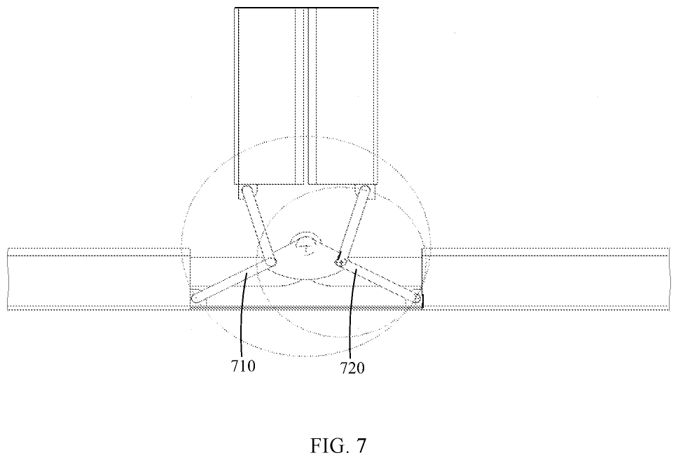

Referring to FIG. 1 to FIG. 7, embodiments of this application disclose an electronic device, including a first folding portion 100, a second folding portion 200, a connecting portion 300, a flexible screen 400, a rotating shaft assembly 500, and a connecting rod assembly 700.

The first folding portion 100 and the second folding portion 200 are folding portions of the electronic device, and the first folding portion 100 and the second folding portion 200 are rotatably connected, so that relative rotation between the first folding portion 100 and the second folding portion 200 can be implemented, and then the electronic device may be switched between a folding state and an unfolding state.

The first folding portion 100, the second folding portion 200, and the connecting portion 300 form a support structure, and the flexible screen 400 and the rotating shaft assembly 500 are respectively disposed on a first surface and second surface of the support structure, so that the first surface of the support structure is provided with the flexible screen 400, and the second surface of the support structure is provided with the rotating shaft assembly 500. It should be noted that the first surface of the support structure is an outer side surface of the electronic device, and the second surface of the support structure is an inner side surface of the electronic device.

The rotating shaft assembly 500 is an intermediate connection mechanism for implementing rotation of the first folding portion 100 relative to the second folding portion 200. The rotating shaft assembly 500 may include a rotating shaft 510, and the rotating shaft 510 is located at a position that is on the second surface and that is opposite to the connecting portion 300. While the electronic device is being unfolded or folded, the first folding portion 100 and/or the second folding portion 200 rotate relative to the rotating shaft 510. In a case that the electronic device is in the folding state, the flexible screen 400 is located on an outer side of the electronic device, and a first portion that is of the flexible screen 400 and that is on the first folding portion 100 is disposed opposite to a second portion that is of the flexible screen 400 and that is on the second folding portion 200. Therefore, the flexible screen 400 can follow the first folding portion 100 and the second folding portion 200 to rotate relatively, so as to be unfolded or folded. In a case that the electronic device is in the unfolding state, the flexible screen 400 is unfolded accordingly, thus forming a relatively large display area. In a case that the electronic device is in the folding state, the flexible screen 400 is folded accordingly, thereby making an external size of the electronic device relatively small and ensuring portability of the electronic device.

The connecting rod assembly 700 includes a first connecting rod 710 and a second connecting rod 720. A first end of the first connecting rod 710 is rotatably connected to the rotating shaft assembly 500, and a second end of the first connecting rod 710 is connected to the first folding portion 100. A first end of the second connecting rod 720 is rotatably connected to the rotating shaft assembly 500, and a second end of the second connecting rod 720 is connected to the second folding portion 200. In this case, the first connecting rod 710 and the second connecting rod 720 can both play a connection role, so that the rotating shaft assembly 500 may be better connected to the first folding portion 100 and the second folding portion 200, and the rotating shaft assembly 500 may be prevented from falling off.

In addition, while the electronic device is being folded or unfolded, the first connecting rod 710 and the second connecting rod 720 rotate along with relative rotation of the first folding portion 100 and the second folding portion 200. While the electronic device is being folded, the first connecting rod 710 and the second connecting rod 720 are folded along with folding between the first folding portion 100 and the second folding portion 200. While the electronic device is being unfolded, the first connecting rod 710 and the second connecting rod 720 are unfolded along with unfolding between the first folding portion 100 and the second folding portion 200. During unfolding, the first connecting rod 710 may act as a support between the rotating shaft assembly 500 and the first folding portion 100, and the second connecting rod 720 may act as a support between the rotating shaft assembly 500 and the second folding portion 200. Therefore, the first folding portion 100 and the second folding portion 200 enable the connecting portion 300 to stretch relatively well, so that a length of the connecting portion is increased, and then the flexible screen 400 may be in a stretching state.

In a case that the electronic device is being unfolded, the first connecting rod 710 acts as a support between the rotating shaft 510 and the first folding portion 100, and the second connecting rod 720 acts as a support between the rotating shaft 510 and the second folding portion 200. In this case, the first connecting rod 710 and the second connecting rod 720 may drive the first folding portion 100 and the second folding portion 200 to be away from each other. Therefore, when the electronic device is being unfolded, the first connecting rod 710 drives the first folding portion 100 to rotate toward a direction away from the second folding portion 200, and the second connecting rod 720 drives the second folding portion 200 to rotate toward a direction away from the first folding portion 100. Then, the first folding portion 100 and the second folding portion 200 are away from each other, so that the electronic device may be unfolded at an angle required by a user, to meet requirements of the user.

By improving a structure of an electronic device in the related art, the electronic device disclosed in this embodiment of this application is provided with the first folding portion 100, the second folding portion 200, the connecting portion 300, the flexible screen 400, the rotating shaft assembly 500, and the connecting rod assembly 700. The first folding portion 100 is rotatably connected to the second folding portion 200 through the connecting portion 300. The flexible screen 400 and the rotating shaft assembly 500 are respectively disposed on the first surface and second surface of the support structure formed by the first folding portion 100, the second folding portion 200, and the connecting portion 300. In addition, the connecting rod assembly 700 is connected to the rotating shaft assembly 500, the first folding portion 100, and the second folding portion 200, that is, the connecting rod assembly 700 acts as a relatively good support when the first folding portion 100 and the second folding portion 200 rotate relative to each other. While the first folding portion 100 and the second folding portion 200 rotate relative to each other to be unfolded, the first connecting rod 710 and the second connecting rod 720 drive the first folding portion 100 and the second folding portion 200 to be away from each other. Due to unfolding support of the first connecting rod 710 and the second connecting rod 720, a distance between adjacent edges of the first folding portion 100 and the second folding portion 200 is not reduced due to the rotating shaft assembly 500, and then the flexible screen 400 can be stretched well, an area where the flexible screen 400 is opposite to the connecting portion 300 is not wrinkled, and user experience can be improved finally.

In this embodiment of this application, a distance between the first end of the first connecting rod 710 and the first end of the second connecting rod 720 is greater than a diameter of the rotating shaft 510. In a case that the electronic device is in the folding state, a distance between the first end of the first connecting rod 710 and a center of the rotating shaft 510 is a first distance. In a case that the electronic device is in the unfolding state, the distance between the first end of the first connecting rod 710 and the center of the rotating shaft 510 is a second distance. The first distance is less than the second distance. While the electronic device is being unfolded, the first connecting rod 710 rotates around the first end of the first connecting rod 710 in a first direction, and the first folding portion 100 rotates around the rotating shaft 510 in the first direction, so that the first end of the first connecting rod 710 is an end close to the connecting rod assembly 700, and the first direction is a direction in which the first folding portion 100 is away from the second folding portion 200. The second connecting rod 720 rotates around the first end of the second connecting rod 720 in a second direction, and the second folding portion 200 rotates around the rotating shaft 510 in the second direction, so that the first end of the second connecting rod 720 is an end close to the connecting rod assembly 700, and the second direction is a direction in which the second folding portion 200 is away from the first folding portion 100. In this case, while the electronic device is being unfolded, a distance between the first end of the first connecting rod 710 and the first end of the second connecting rod 720 is unchanged, but the other end of the first connecting rod 710 and the other end of the second connecting rod 720 are away from each other, and the first folding portion 100 and the second folding portion 200 rotate respectively toward the first direction and the second direction, so that the first connecting rod 710 and the second connecting rod 720 respectively drive the first folding portion 100 and the second folding portion 200 to be away from each other, finally achieving the unfolding state of the electronic device. In some embodiments, the first direction is opposite to the second direction.

In an embodiment of this application, the rotating shaft assembly 500 is an intermediate connecting mechanism for the first folding portion 100 to rotate relative to the second folding portion 200. The rotating shaft assembly 500 may include the rotating shaft 510, a first rotating member 520, and a second rotating member 530. The first rotating member 520 and the second rotating member 530 are rotatably connected by the rotating shaft 510, so that the first rotating member 520 and the second rotating member 530 can rotate relative to each other.

In an embodiment of this application, the first folding portion 100 may be provided with first guide space, and the second folding portion 200 is provided with second guide space. Both the first guide space and the second guide space play a guide role, and further match the first rotating member 520 and the second rotating member 530 respectively.

A first end of the first rotating member 520 is connected to the rotating shaft 510, a second end of the first rotating member 520 extends into the first guide space, and the first rotating member 520 may slidably match the first guide space along with relative rotation between the first folding portion 100 and the second folding portion 200. Therefore, while the first rotating member 520 and the second rotating member 530 are rotating, rotation between the first folding portion 100 and the second folding portion 200 can be better adapted, which helps the first folding portion 100 and the second folding portion 200 be away from each other.

A first end of the second rotating member 530 is connected to the rotating shaft 510, a second end of the second rotating member 530 extends into the second guide space, and the second rotating member 530 may slidably match the second guide space along with the relative rotation between the first folding portion 100 and the second folding portion 200. Therefore, while the first rotating member 520 and the second rotating member 530 are rotating, rotation between the first folding portion 100 and the second folding portion 200 can be better adapted, which helps the first folding portion 100 and the second folding portion 200 be away from each other.

The slidable matching can better prevent wrinkling of the flexible screen 400 caused by a difference in a rotation radius between the first rotating member 520 and the second rotating member 530 and a rotation radius between the first folding portion 100 and the second folding portion 200, further reducing the wrinkling of the flexible screen 400.

In a further technical solution, the connecting portion 300 may be a sheet-like elastic member with a thin thickness, thus occupying less space. In a further technical solution, the first folding portion 100, the second folding portion 200, and the connecting portion 300 form an accommodating groove 600, and the rotating shaft 510, a portion of the first rotating member 520, and a portion of the second rotating member 530 are all disposed in the accommodating groove 600. In this case, during assembly of the rotating shaft 510, the first rotating member 520, and the second rotating member 530, space of the accommodating groove 600 may be fully utilized, so that a structure of the electronic device may be more compact, and the electronic device may be designed to be thinner.

There are many kinds of sheet-like elastic members. For example, the sheet-like elastic member may be an elastic plastic member. In some embodiments, the sheet-like elastic member may be a metal sheet, such as a steel sheet. The metal sheet has relatively good toughness and deformation performance, which helps improvement of connection stability. In some embodiments, the metal sheet may be assembled with the first folding portion 100 and the second folding portion 200 by rivets, welding, bonding, or the like.

There may be multiple kinds of structures of the first folding portion 100 and the second folding portion 200. As described above, the first folding portion 100 is provided with the first guide space, and the second folding portion 200 is provided with the second guide space. Specifically, the first folding portion 100 may form multiple kinds of first guide space, and the second folding portion 200 may form multiple kinds of second guide space.

In some embodiments, the first guide space may be a first guide groove 111, and the second guide space may be a second guide groove 211. For example, the first guide groove 111 and the first rotating member 520 are slidably matched in a length direction of the first guide groove 111, and the first rotating member 520 and the first guide groove 111 are limitedly matched in a depth direction of the first guide groove 111, so that the first rotating member 520 is prevented from being separated from a notch of the first guide groove 111 during rotation. Similarly, the second guide groove 211 and the second rotating member 530 are slidably matched in a length direction of the second guide groove 211, and the second rotating member 530 and the second guide groove 211 are limitedly matched in a depth direction of the second guide groove 211, so that the second rotating member 530 is prevented from being separated from a notch of the second guide groove 211 during rotation. The first guide groove 111 and the second guide groove 211 may be dovetail grooves, and both the first rotating member 520 and the second rotating member 530 may have structures adapted to the dovetail grooves. The first guide space has a simple structure and is easy to achieve.

Referring to FIG. 2, in some alternative embodiments, a first folding portion 100 may include a first folding body 110 and a first cover plate 120. The first folding body 110 may be provided with a first guide groove 111. The first guide groove 111 extends toward a direction away from a rotating shaft assembly 500, and an end that is of the first guide groove 111 and that is adjacent to the rotating shaft assembly 500 is the first open end. The first cover plate 120 is disposed on a notch of the first guide groove 111 and forms first guide space with the first guide groove 111. A second end of a first rotating member 520 passes through the first open end and extends into the first guide space. The first guide space enclosed by members can shield a larger area of the first rotating member 520, which can better prevent poor sliding caused by intrusion of a foreign substance. In addition, the first cover plate 120 can cover the first guide groove 111, which helps improvement of appearance performance of the electronic device.

In a further technical solution, an inner side wall of the first guide groove 111 may be provided with a first support table 112, and the first cover plate 120 is supported on the first support table 112. A surface that is of the first cover plate 120 and that is opposite to the first guide space is a first outer surface, and the first outer surface is coplanar with a surface where the notch of the first guide groove 111 is located, which helps improvement of the appearance performance of the electronic device. In addition, during assembly of the first cover plate 120, the first support table 112 can play a positioning role, to improve assembling performance of the first cover plate 120 and the first guide groove 111.

Similarly, the second folding portion 200 may include a second folding body 210 and a second cover plate 220. The second folding body 210 may be provided with a second guide groove 211, the second guide groove 211 extends toward a direction away from the rotating shaft assembly 500, and an end that is of the second guide groove 211 and that is adjacent to the rotating shaft assembly 500 is a second open end. The second cover plate 220 is disposed on a notch of the second guide groove 211, and forms second guide space with the second guide groove 211. A second end of the second rotating member 530 passes through the second open end and extends into the second guide space. The second guide space enclosed by members can shield a larger area of the second rotating member 530, which can better prevent poor sliding caused by intrusion of a foreign substance. In addition, the second cover plate 220 can cover the second guide groove 211, which helps improvement of appearance performance of the electronic device.

In a further technical solution, an inner side wall of the second guide groove 211 may be provided with a second support table 212, and the second cover plate 220 is supported on the second support table 212. A surface that is of the second cover plate 220 and that is opposite to the second guide space is a second outer surface, and the second outer surface is coplanar with a surface where the notch of the second guide groove 211 is located, which helps improvement of the appearance performance of the electronic device. In addition, during assembly of the second cover plate 220, the second support table 212 can play a positioning role, to improve assembling performance of the second cover plate 220 and the second guide groove 211.

As described above, a first end of a first connecting rod 710 and a first end of a second connecting rod 720 are both rotatably connected to a rotating shaft 510. In some embodiments, the first end of the first connecting rod 710 and the first end of the second connecting rod 720 may be directly connected to the rotating shaft 510 or indirectly connected to the rotating shaft 510.

In the electronic device disclosed in an embodiment of this application, an end of the rotating shaft 510 may be provided with a sheet-like fixing portion 540. The sheet-like fixing portion 540 has a flange protruding from a peripheral wall surface of the rotating shaft 510. Afirst connecting hole 511 may be disposed in a portion that is of the flange and that is adjacent to the first folding portion 100, and a second connecting hole 512 may be disposed in a portion that is of the flange and that is adjacent to the second folding portion 200. An end of the first connecting rod 710 is hinged with the first connecting hole 511, and an end of the second connecting rod 720 is hinged with the second connecting hole 512. The sheet-like fixing portion 540 is relatively thin and has a flange protruding from the rotating shaft 510, to help disposing of the first connecting hole 511 and the second connecting hole 512, and further help connection of the first connecting rod 710 and the second connecting rod 720. In this case, the first end of the first connecting rod 710 and the first end of the second connecting rod 720 may be indirectly connected to the rotating shaft 510 through the sheet-like fixing portion 540.

In a further technical solution, the sheet-like fixing portion 540 may be detachably connected to the rotating shaft 510, and in this case, the sheet-like fixing portion 540 may be detached from the rotating shaft 510, which helps subsequent replacement of the sheet-like fixing portion 540.

In the electronic device disclosed in an embodiment of this application, the first connecting rod 710 and the second connecting rod 720 are symmetrically disposed with an axis of the rotating shaft assembly 500 as a central axis, so that connection between the rotating shaft 510 and the first folding portion 100 and connection between the rotating shaft 510 and the second folding portion 200 may be more balanced, which helps improvement of structural stability of the electronic device. In some embodiments, in a case that the rotating shaft assembly 500 includes the rotating shaft 510, the axis of the rotating shaft 510 is collinear with an axis of the rotating shaft assembly 500.

In the electronic device disclosed in an embodiment of this application, the number of the connecting rod assembly 700 may be one or multiple. In some embodiments, there may be two connecting rod assemblies 700, and the two connecting rod assemblies 700 are respectively connected to two ends of the rotating shaft assembly 500. Therefore, the two ends of the rotating shaft assembly 500 are better connected, so that the two ends of the rotating shaft assembly 500 are limited, to prevent the first folding portion 100 from being separated from the second folding portion 200, and the rotating shaft assembly 500 and the first folding portion 100 as well as the rotating shaft assembly 500 and the second folding portion 200 can be better stretched. In a case that the rotating shaft assembly 500 includes the rotating shaft 510, the two connecting rod assemblies 700 are connected to the two ends of the rotating shaft 510 respectively.

The electronic device disclosed in the embodiments of this application may be a mobile phone, a tablet computer, an ebook reader, a game machine, a wearable device, and the like. The embodiments of this application do not limit a specific type of the electronic device.

It should be noted that, in this specification, the terms “include”, “comprise”, or their any other variant is intended to cover a non-exclusive inclusion, so that a process, a method, an article, or an apparatus that includes a list of elements not only includes those elements but also includes other elements which are not expressly listed, or further includes elements inherent to such process, method, article, or apparatus. In the absence of more restrictions, an element defined by the statement “including a . . . ” does not preclude the presence of other identical elements in the process, method, article, or apparatus that includes the element.

The embodiments of this application are described above with reference to the accompanying drawings, but this application is not limited to the foregoing implementations. The foregoing implementations are merely schematic instead of restrictive. Under enlightenment of this application, a person of ordinary skills in the art may make many forms without departing from aims and the protection scope of claims of this application, all of which fall within the protection scope of this application.

1. An electronic device, comprising:
a first folding portion;
a second folding portion;
a connecting portion;
a flexible screen;
a rotating shaft assembly; and
a connecting rod assembly,
wherein:
the first folding portion is rotatably connected to the second folding portion through the connecting portion, wherein:
the first folding portion, the second folding portion, and the connecting portion form a support structure, and
the flexible screen and the rotating shaft assembly are respectively disposed on a first surface and a second surface of the support structure;
the rotating shaft assembly comprises a rotating shaft, wherein:
the rotating shaft is located at a position that is on the second surface and that is opposite to the connecting portion,
while the electronic device is being unfolded or folded, the first folding portion or the second folding portion rotate relative to the rotating shaft,
in a case that the electronic device is in a folding state, the flexible screen is located on an outer side of the electronic device, and
a first portion that is of the flexible screen and that is on the first folding portion is disposed opposite to a second portion that is of the flexible screen and that is on the second folding portion;
the connecting rod assembly comprises a first connecting rod and a second connecting rod, wherein:
a first end of the first connecting rod is rotatably connected to the rotating shaft assembly, and a second end of the first connecting rod is connected to the first folding portion,
a first end of the second connecting rod is rotatably connected to the rotating shaft assembly, and a second end of the second connecting rod is connected to the second folding portion; and
while the electronic device is being unfolded, the first connecting rod and the second connecting rod respectively drive the first folding portion and the second folding portion to be away from each other, and the connecting portion is increased.

2. The electronic device according to claim 1, wherein a distance between the first end of the first connecting rod and the first end of the second connecting rod is greater than a diameter of the rotating shaft.

3. The electronic device according to claim 1,
wherein:
the rotating shaft assembly further comprises a first rotating member and a second rotating member, wherein the first rotating member and the second rotating member are rotationally connected through the rotating shaft;
the first folding portion comprises first guide space, and the second folding portion comprises with second guide space;
a first end of the first rotating member is rotatably connected to the rotating shaft, a second end of the first rotating member extends into the first guide space, and the first rotating member slidably matches the first guide space along with relative rotation between the first folding portion and the second folding portion; and
a first end of the second rotating member is rotatably connected to the rotating shaft, a second end of the second rotating member extends into the second guide space, and the second rotating member slidably matches the second guide space along with the relative rotation between the first folding portion and the second folding portion.

4. The electronic device according to claim 3,
wherein:
the connecting portion is a sheet-like elastic member,
the first folding portion, the second folding portion, and the connecting portion form an accommodating groove,
the rotating shaft, a portion of the first rotating member, and a portion of the second rotating member are all disposed in the accommodating groove, and
the first guide space and the second guide space are both in communication with the accommodating groove.

5. The electronic device according to claim 3, wherein the first folding portion comprises a first folding body and a first cover plate,
wherein:
the first folding body comprises a first guide groove,
the first guide groove extends toward a direction away from the rotating shaft assembly,
an end that is of the first guide groove and that is adjacent to the rotating shaft assembly is a first open end,
the first cover plate is disposed on a notch of the first guide groove and forms the first guide space with the first guide groove, and
the second end of the first rotating member passes through the first open end and extends into the first guide space.

6. The electronic device according to claim 5, wherein an inner side wall of the first guide groove comprises a first support table,
wherein:
the first cover plate is supported on the first support table,
a surface that is of the first cover plate and that is opposite to the first guide space is a first outer surface, and
the first outer surface is coplanar with a surface where the notch of the first guide groove is located.

7. The electronic device according to claim 5, wherein the second folding portion comprises a second folding body and a second cover plate,
wherein:
the second folding body comprises a second guide groove,
the second guide groove extends toward a direction away from the rotating shaft assembly, and
an end that is of the second guide groove and that is adjacent to the rotating shaft assembly is a second open end,
the second cover plate is disposed on a notch of the second guide groove and forms the second guide space with the second guide groove, and
the second end of the second rotating member passes through the second open end and extends into the second guide space.

8. The electronic device according to claim 7, wherein an inner side wall of the second guide groove comprises a second support table,
wherein: the second cover plate is supported on the second support table,
a surface that is of the second cover plate and that is opposite to the second guide space is a second outer surface, and
the second outer surface is coplanar with a surface where the notch of the second guide groove is located.

9. The electronic device according to claim 1, wherein an end of the rotating shaft comprises a sheet-like fixing portion,
wherein:
the sheet-like fixing portion comprises a flange protruding from a peripheral wall surface of the rotating shaft,
a first connecting hole is disposed in a portion that is of the flange and that is adjacent to the first folding portion, and
a second connecting hole is disposed in a portion that is of the flange and that is adjacent to the second folding portion,
an end of the first connecting rod is hinged with the first connecting hole, and
an end of the second connecting rod is hinged with the second connecting hole.

10. The electronic device according to claim 9, wherein the sheet-like fixing portion is detachably connected to the rotating shaft.
